(19) United States
(12) Patent Application Publication
(10) Pub. No.: US 2007/0158769 A1
(43) Pub. Date: Jul. 12, 2007

(54) Integrated CMOS-MEMS technology for wired implantable sensors

(75) Inventor: Liang You, Duluth, GA (US)

Correspondence Address: Law Offices of Kenneth W. Float, 2095 Hwy. 211 NW, #2F, Braselton, GA, 30517, US

(73) Assignee: CardioMEMS, Inc.

(21) Appl. No.: 11/546,852

(22) Filed: Oct. 12, 2006

Related U.S. Application Data
(60) Provisional application No. 60/726,948, filed on Oct. 14, 2005.

(51) Int. Cl. H01L 29/84

(52) U.S. Cl. 257/415

(57) ABSTRACT

Disclosed are wired implantable integrated CMOS-MEMS sensors and fabrication methods. A first ceramic substrate comprising a biocompatible material such as fused silica is provided. A polysilicon layer is formed on the first substrate. An integrated circuit is fabricated adjacent to the surface of the first substrate. A passivation layer is formed on the integrated circuit. A conductive area is formed on the passivation layer that provides electrical communication with the integrated circuit. A feedthrough is formed through the first substrate that contacts the conductive area and provides for external electrical communication to the integrated circuit. A second ceramic substrate or cap comprising a biocompatible material is fused to the first substrate so as to form a cavity that encases the integrated circuit and form a sensor. The cavity is preferably a pressure cavity which cooperates to form a pressure sensor

### CROSS-REFERENCE TO RELATED APPLICATIONS

This application is entitled to the filing date of provisional U.S. Patent Application Ser. No. 60/726,948, filed Oct. 14, 2005.

### BACKGROUND

The present invention relates to wired implantable integrated CMOS-MEMS (complementary metal-oxide silicon-microelectromechanical systems) sensors and methods of fabrication.

In the art of capacitive-based pressure sensing as it relates to the medical device industry, it is desirable to incorporate an IC chip into a pressure cavity or chamber. Integration of an IC chip in the pressure cavity can enable enhancements to sensor performance such as lower parasitic capacitance, reduced noise and drift, and sensing accuracy, all while maintaining sufficient miniaturization for intracorporeal use. Prima facie, this approach is straightforward. However, from the standpoint of process integration, incorporating a prefabricated IC chip with a MEMS structure presents many problems.

Regarding process integration and feasibility, the IC chip must be placed on a substrate which eventually forms part of A pressure cavity, and the appropriate interconnects (e.g., signal, power) must be formed between the chip and a sensing capacitor. Therefore, unique techniques in IC chip attachment and interconnection are needed. Also, the process for IC chip attachment must be reliable in testing and process integration as well as achieve a consistent end result.

The IC chip also requires extra space and clearance in the pressure cavity. This increases constraints on the size of the IC chip as well as other functional components of the pressure cavity (e.g. capacitor and feedthroughs, for example).

Finally, the unique IC chip attachment and interconnection between other functional components in the pressure cavity must be amenable to batch fabrication and meet the requirements for sensor performance.

In recent years, there has been a significant increase in the popularity of liquid crystal displays with control circuitry being placed onto glass, e.g. systems on a panel. This technology has been realized through improvements made to thin-film transistors (TFTs) manufactured on glass substrates. The recent popularity of TFTs is a result of the move away from traditional use of amorphous silicon towards polycrystalline silicon (polysilicon). Performance advantages gained through use of polycrystalline silicon have allowed TFTs to be used in applications beyond pixel control transistors.

However, it has not been proposed to use CMOS, e.g., TFT, manufacturing technology to manufacture ceramic sensors. Ceramic packaging technology confers many benefits for sensing, especially in harsh environments. For example, silicon is not recommended for use under DC bias in electrolyte solutions (e.g., marine environments, the human body) due to corrosion issues. Furthermore, marriage of CMOS and TFT technology to the fabrication of ceramic sensors to form active components on the ceramic substrate eliminates the need to use discrete IC's and wire bonding techniques to connect to those ICs. Thus, manufacturing is simplified and such devices can be miniaturized past what is known at the present time while increasing the reliability of the resulting device.

Thus, there is a need for sensors with active circuit components formed directly on an interior surface of a hermetic cavity.

### BRIEF DESCRIPTION OF THE DRAWINGS

The various features and advantages of the present invention may be more readily understood with reference to the following detailed description taken in conjunction with the accompanying drawings, wherein like reference numerals designate like structural elements, and in which:

FIGS. 1a-1n illustrate process steps in an exemplary method for fabricating exemplary wired implantable integrated CMOS-MEMS pressure sensors; and

FIG. 2 illustrates an alternative embodiment of the exemplary wired implantable integrated CMOS-MEMS pressure sensor.

### DETAILED DESCRIPTION

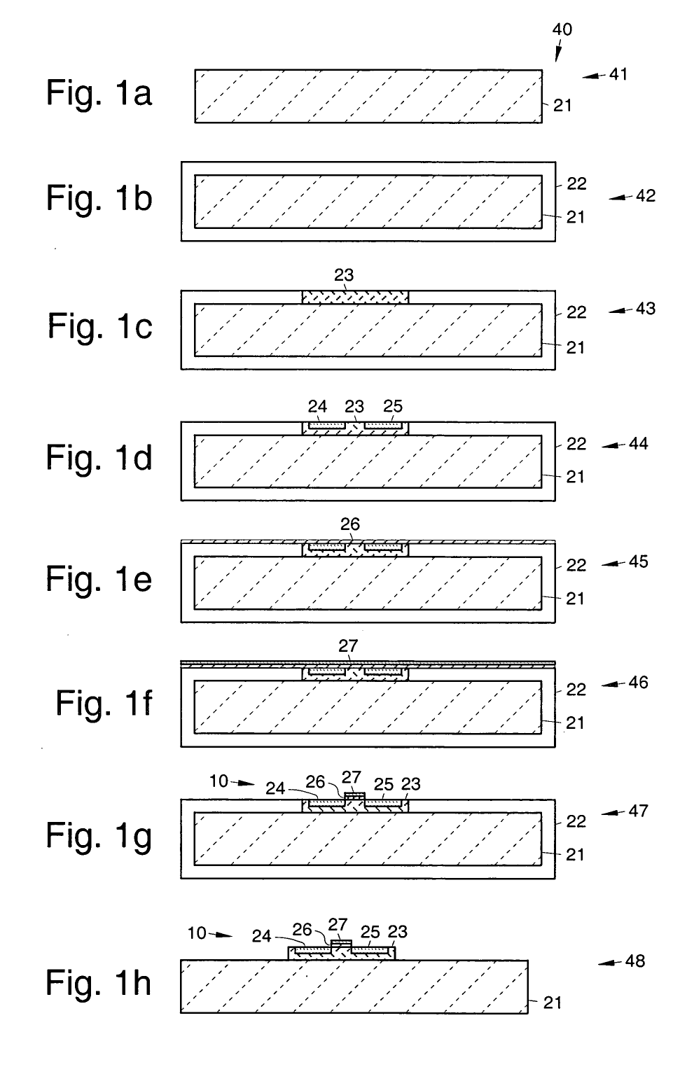

Disclosed are exemplary wired implantable integrated CMOS-MEMS pressure sensing devices 20 or sensors 20 (FIGS. 1m and 1n) and fabrication methods 40 (FIGS. 1a-n). The exemplary wired implantable integrated CMOS-MEMS pressure sensors 20 may be advantageously used in medical applications, such as implanting them in a person's body, for example. Exemplary pressure sensing devices 20 or sensors 20 are hermetic.

The following patent applications are incorporated herein by reference in their entirety: U.S. patent application Ser. No. 10/943,772, filed Sep. 16, 2004, U.S. patent application Ser. No. 11/472,905, filed Jun. 22, 2006, U.S. patent application Ser. No. 11/314,046, filed Dec. 20, 2005, U.S. patent application Ser. No. 11/314,696, filed Dec. 20, 2005, U.S. patent application Ser. No. 11/157,375, filed Jun. 21, 2005, and U.S. patent application Ser. No. 11/204,812, filed Aug. 16, 2005. The following patents are incorporated herein by reference in their entirety: U.S. Pat. No. 6,111,520 issued to Allen et. al., and U.S. Pat. No. 6,278,379 issued to Allen et. Al.

The term hermetic is generally defined as meaning “airtight or impervious to air.” In reality, however, all materials are, to a greater or lesser extent, permeable, and hence specifications must define acceptable levels of hermeticity. An acceptable level of hermeticity for a pressure sensor, for example, is therefore a rate of fluid ingress or egress that changes the pressure in the internal reference volume (pressure chamber) by an amount preferably less than 10 percent of the external pressure being sensed, more preferably less than 5 percent, and most preferably less than 1 percent over the accumulated time over which the measurements will be taken. In many biological applications, for example, an acceptable pressure change in the pressure chamber is on the order of 1.5 mm Hg/year. It is to be understood that that the present invention is not limited only to hermetic sensors 20 or sensing devices 20 that sense pressure, but may include any sensor 20 or device 20 that employs a hermetic chamber or cavity.

The manufacturing process suitable for producing the wired implantable pressure sensors 20 using integrated CMOS-MEMS technology involves the use of high resistivity polysilicon as a substrate for an integrated circuit (IC) chip. This process is similar to metal oxide semiconductor field effect transistor (MOSFET) fabrication processes that fabricate MOS semiconductor devices on a glass substrate. The traditional MOS processes produce an integrated circuit (IC) structure that is similar to the disclosed processes that produce integrated pressure sensors, except that a different substrate material is employed. Furthermore, processing parameters due to considerations of grain boundary effect, and therefore the IC design, are different from the processing performed to fabricate conventional MOS semiconductor devices.

FIGS. 1a-1n illustrate process steps in an exemplary method 40 for fabricating exemplary wired implantable integrated CMOS-MEMS pressure sensors 20. Details of the exemplary method 40 and pressure sensor 20 are as follows.

As shown in FIG. 1a, a 300-500 μm, thick wafer 21, for example, which comprises fused silica, or other biocompatible material, is provided 41 as a substrate 21. As shown in FIG. 1b, low pressure chemical vapor deposition (LPCVD), for example, may be used to deposit 42 a 2-5 μm-thick, for example, high resistivity, high compressive stress polysilicon layer 22 on the fused silica substrate 21, which may be subsequently annealed to provide stress relief. Compressive stresses in the polysilicon layer 22 compensate to an extent for the coefficient of thermal expansion (CITE) mismatch between the polysilicon layer 22 and the fused silica substrate 21.

Standard IC processes relating to polysilicon thin film transistor (TFT) technology are used to incorporate an IC chip 10 (FIGS. 1c-1k) in the polysilicon layer 22. As shown in FIG. 1c, photolithography and ion implantation 43 of P+ ions are performed to provide a CMOS active area 23 in the polysilicon layer 22. As shown in FIG. 1d, photolithography and ion implantation 44 are performed to form sources 24 and drains 25 for CMOS circuitry comprising the IC chip 10 along with any resistors or capacitors required for the IC chip 10. As shown in FIG. 1e, gate oxide 26 is grown 45 on the substrate 21, and as shown in FIG. 1f, a gate 27, comprising metal or polysilicon, is deposited 46.

As shown in FIG. 1g, photolithography and metal/gate oxide patterning are performed to remove 47 unwanted gate oxide 26 and gate 27 material. As shown in FIG. 1h, unwanted polysilicon 22 is etched away 48 via photolithography and reactive ion etching (RIE), for example. Then, as shown in FIG. 1i, the IC chip 10 is passivated 49 with a passivation layer 28 comprising silicon nitride, for example, in a manner known in the art. As shown in FIG. 1j, a layer of conductive material 29, such as polysilicon, metal or any other conductor (known in the art, for example, is deposited 50 on the silicon nitride passivation layer 28. As shown in FIG. 1k, photolithography and nitride etching are performed to remove 51 portions of the layer of conductive material 29 and create a conductive area 30, or metal interconnect 30, for electrical communication.

Subsequently, as shown in FIG. 11, a metal feedthrough 31 is formed 52 in order to establish electrical communication with the IC chip 10. In order to create the feedthrough 31, a metal layer is deposited and the processes of photolithography and metal etching are used to define the final form of the metal feedthrough 31. Wafer through holes 32 may be created by etching through the lower side of the substrate 21 to expose the back side of the conductive area 30, or metal interconnect 30, such as by using laser drilling or deep RIE, for example. A thick refractory metal such as titanium, for example, is deposited into the through holes 32 by low pressure plasma spraying (LPPS) or other suitable technique such as pad laser bonding or welding, or molten salt electroplating, or the like.

Then, as shown in FIG. 1m, conventional metal deposition and patterning techniques are employed to define 53 a feedthrough cover 33 on the substrate 21 comprising the IC chip 10. Other components, such as a capacitor electrode, may be formed concurrently with this step by suitable mask selection. Feedthroughs (lateral or vertical types) may be created using laser drilling, ion milling or ultrasonic drilling, for example, to contact the back side of the feedthrough cover 33, and the resulting hole is filled with metal such as by electroplating or depositing metal solder, for example.

As shown in FIG. 1n, a cap 34 or second substrate 34 comprising fused silica, or other biocompatible material, configured to have a deep cavity 35 formed therein, is disposed on the substrate 21 containing the IC chip 10. Then, the two substrates 21, 34 are simultaneously cut and fused together 53 using a CO₂ laser, for example, operating at a wavelength of about 10 microns, for example. This produces a hermetically sealed sensor 20. As an alternative to using a highly localized source of heat (such as a laser) to heat bond and reduce the sensor 20 to the final dimensions simultaneously, either anodic or eutectic bonding could be used to seal the sensor at the wafer level and dicing used to individualize the sensor 20.

The substrate 21 and the cap 34 are made of fused silica, for example, and thus the sealed structure comprising the pressure sensor 20 is biologically compatible with human organs and tissue. Consequently, the pressure sensor 20 may be implanted inside the human body, such as in a person's heart, or in an area of an aneurism, for example.

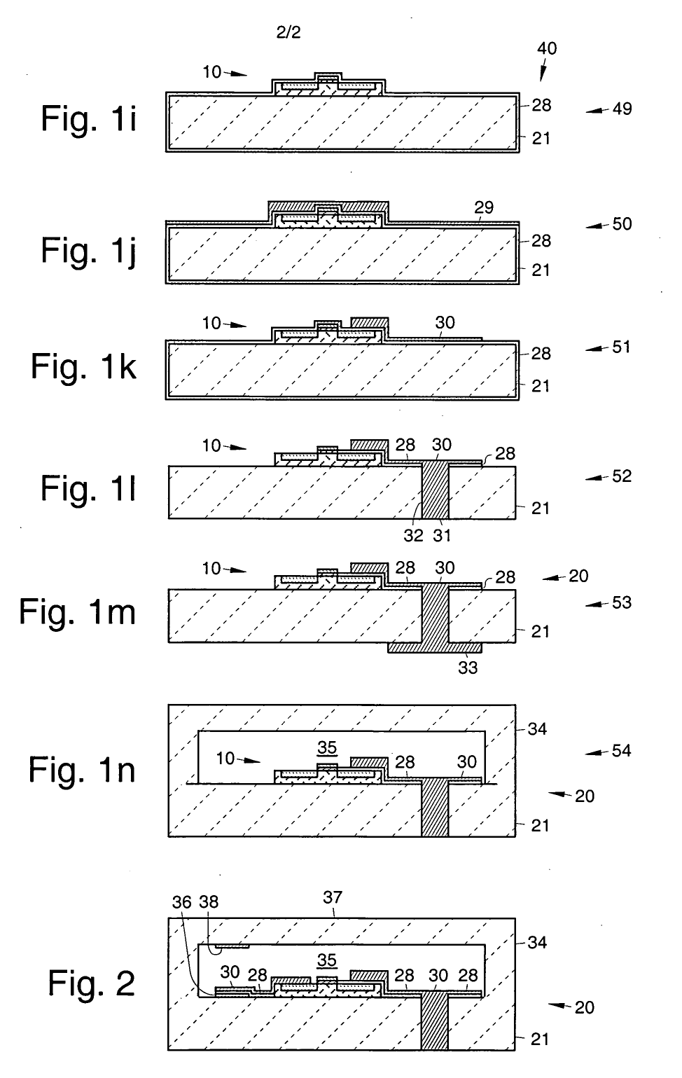

FIG. 2 illustrates an embodiment of the exemplary wired implantable integrated CMOS-MEMS pressure sensor 20. In this embodiment, a pair of separated lower capacitor electrodes 36 is deposited or otherwise formed on the substrate 21, and the fused silica cap 34 is processed such that a wall of the cavity 35 opposite to the substrate 21 forms a deflective region 37 that changes position in response to pressure. Two conductive areas 30, or metal interconnects 30, are formed over a passivation layer 28 comprising silicon nitride, for example, that couple the respective lower capacitor electrodes 36 to the sources 24, for example, of the IC chip 10.

Further, an upper capacitor electrode 38 is deposited or otherwise formed on the deflective region 37 opposite to the pair of lower capacitor electrodes 36 using the metal deposition and patterning techniques described above. The capacitor electrodes 36, 38 form a capacitor that is configured so that its characteristic capacitance value varies in response to a physical property, or changes in a physical property, of a person, for example. When the cap 34 and substrate 21 are cut and fused together (FIG. 1n), a pressure cavity 35 is formed that encases the capacitor in the pressure cavity 35.

Thus, wired implantable integrated CMOS-MEMS sensors, including pressure sensors, and fabrication methods have been disclosed. It is to be understood that the above-described embodiments are merely illustrative of some of the many specific embodiments that represent applications of the principles discussed above. Clearly, numerous and other arrangements can be readily devised by those skilled in the art without departing from the scope of the invention.

What is claimed is:

1. Apparatus comprising:
a first substrate comprising a ceramic material;
an integrated circuit formed on the first substrate;
at least one conductive feedthrough formed through the first substrate that is in electrical communication with the integrated circuit; and
a second substrate comprising a ceramic material that is hermetically sealed to the first substrate to define an cavity that encloses the integrated circuit, which cavity and integrated circuit cooperate to provide a sensing apparatus.

2. The apparatus recited in claim 1 further comprising:
a pair of lower capacitor electrodes formed on the first substrate that are respectively coupled to the integrated circuit;
wherein the second substrate is configured to have a deflective region that changes position in response to pressure; and
an upper capacitor electrode formed on the deflective region.

3. The apparatus recited in claim 1 wherein the first and second substrates are comprised of glass, fused silica, sapphire, quartz or silicon.

4. The apparatus recited in claim 3 wherein the integrated circuit is passivated using silicon nitride.

5. Apparatus comprising:
a first fused silica substrate;
an integrated circuit formed on the first fused silica substrate;
a feedthrough formed through the first fused silica substrate that in electrical communication with the integrated circuit; and
a second fused silica substrate sealed to the first fused silica substrate to define a cavity that encloses the integrated circuit, which cavity and integrated circuit cooperate to provide a sensing apparatus.

6. The apparatus recited in claim 5 further comprising:
at least one lower capacitor electrode formed on the first fused silica substrate;
a deflective region that changes position in response to pressure formed in the cavity; and
an upper capacitor electrode formed on the deflective region.

7. A method of fabricating implantable pressure sensing apparatus comprising:
providing a first substrate comprising a ceramic material;
forming a polysilicon layer on the first substrate;
fabricating an integrated circuit adjacent to a surface of the first substrate;
forming a passivation layer on the integrated circuit;
forming a conductive area on the passivation layer that provides electrical communication to the integrated circuit;
forming a feedthrough through the first substrate that contacts the conductive area that provides for external electrical communication to the integrated circuit; and
fusing a second substrate comprising a ceramic material to the first substrate to form a hermetic cavity that encases the integrated circuit.

8. The method recited in claim 7 wherein the first and second substrates comprise fused silica.

9. The method recited in claim 7 further comprising annealing the polysilicon layer to provide stress relief.

10. The method recited in claim 7 wherein the integrated circuit fabricated by:
forming an active area in the polysilicon layer;
forming source and drain electrodes in the active area;
growing gate oxide on the substrate; and
forming a gate on the gate oxide.

11. The method recited in claim 7 wherein the active area in the polysilicon layer and the source and drain electrodes are formed using photolithography and ion implantation.

12. The method recited in claim 7 wherein the gate comprises metal or polysilicon.

13. The method recited in claim 7 where the integrated circuit is passivated using silicon nitride.
